(19) United States
(12) Patent Application Publication
(10) Pub. No.: US 2025/0105065 A1
(43) Pub. Date: Mar. 27, 2025

(54) RADIO FREQUENCY INDUCED MICRO LED INSPECTION

(71) Applicant: Orbotech Ltd., Yavne (IL)

(72) Inventor: Arie Glazer, Mevaseret (IL)

(21) Appl. No.: 18/472,555

(22) Filed: Sep. 22, 2023

(51) Int. Cl. H01L 21/66; G06T 7/00; H01L 21/67; H01L 25/075; H01L 33/00

(52) U.S. Cl. CPC H01L 22/20; G06T 7/0004; G06T 7/97; H01L 21/67288; H01L 25/0753; G06T 2207/30148; H10H 20/01

(57) ABSTRACT

The system includes a glass panel, a radio frequency generator, a camera, and a processor. The glass panel includes a conductive layer, and the conductive layer is disposed on top of an LED. The radio frequency generator is configured to apply a radio frequency signal to the glass panel, and the radio frequency signal illuminates the LED by induction through the conductive layer. The camera is configured to capture an image of the LED illuminated by the radio frequency signal. The processor is in electronic communication with the camera and is configured to receive the image from the camera and determine whether the LED is a defective LED or a functioning LED based on the image of the LED.

### FIELD OF THE DISCLOSURE

This disclosure relates to micro LED manufacturing and, more particularly, to inspection processes for micro LEDs and manufacturing micro LED displays.

### BACKGROUND OF THE DISCLOSURE

In the manufacturing of micro LEDs, thousands of LEDs (less than 100 μm in size) are fabricated on a single semiconductor substrate. Each micro LED must be separated from the substrate (and the other LEDs) to be assembled into a micro LED display panel. In this process, inspection and testing is used to ensure that each LED is functional before it is placed in the display panel assembly to avoid defective LEDs in the display panel. Given the massive amount of micro LEDs on a small substrate, testing each LED can be a very difficult and time consuming process.

Typical LED testing includes photoluminescence (PL) and electroluminescence (EL) tests. PL tests can test LED chips without contact, but have a lower detection efficiency compared to EL test. EL tests are able to identify more defects, but they test LED chips by setting up electric currents which requires contacting the LED chips that might lead to chip damages. For micro LED inspection, applying EL tests can be very difficult and slow as the chip size is too small for conventional testing equipment, and using PL tests might miss some defects, resulting in lower efficiency.

Therefore, what is needed is a method of micro LED inspection that is contactless and has high detection efficiency.

### BRIEF SUMMARY OF THE DISCLOSURE

An embodiment of the present disclosure provides a system. The system may comprise a glass panel comprising a conductive layer. The conductive layer may be disposed on top of an LED. The system may further comprise a radio frequency generator configured to apply a radio frequency signal to the glass panel. The radio frequency signal may illuminates the LED by induction through the conductive layer. The system may further comprise a camera configured to capture an image of the LED illuminated by the radio frequency signal. The system may further comprise a processor in electronic communication with the camera that is configured to receive the image from the camera and determine whether the LED is a defective LED or a functioning LED based on the image of the LED.

In some embodiments, the radio frequency signal has a frequency of 5 to 10 MHz.

In some embodiment, the LED may comprise an array of LEDs disposed on a substrate, and the glass panel may be disposed on top of the array of LEDs.

In some embodiments, the radio frequency signal applied to the glass panel may simultaneously illuminate each LED of the array of LEDs by induction through the conductive layer.

In some embodiments, the system may further comprise a stage configured to move in a plane perpendicular to an optical axis of the camera. The substrate may be disposed on the stage. The camera may be configured to capture an image of at first LED set of the array of LEDs within the field of view of the camera, and by moving the stage relative to the camera, the camera may be further configured to capture an image of a second LED set of the array of LEDs within the field of view of the camera, the second LED set containing at least some LEDs not present in the first LED set or may be a subset of the first LED set.

In some embodiments the LED may have a lateral chip structure.

In some embodiments, the conductive layer may be disposed on a bottom surface of the glass panel, and the LED may contact the conductive layer.

In some embodiments, the conductive layer may comprise indium tin oxide (ITO).

In some embodiments, the processor may be configured to determine whether the LED is a defective LED or a functioning LED by: determining an illumination intensity of the LED based on the image; and comparing the illumination intensity of the LED to a preset threshold. The LED may be a defective LED if the illumination intensity is less than the preset threshold, and the LED may be a functioning LED if the illumination intensity is greater than or equal to the preset threshold.

Another embodiment of the present disclosure provides a method The method may comprise: generating a radio frequency signal using a radio frequency generator; applying the radio frequency signal to a glass panel, wherein the glass panel comprises a conductive layer, and the conductive layer is disposed on top of an LED; emitting light from the LED based on induction between the conductive layer and the LED caused by the radio frequency signal; capturing an image using a camera based on the light emitted from the LED; and determining, using a processor, whether the LED is a defective LED or a functioning LED based on the image of the LED.

In some embodiments, the LED may comprise an array of LEDs disposed on a substrate, and the glass panel is disposed on top of the array of LEDs, and applying the radio frequency signal to the glass panel may simultaneously illuminate the array of LEDs by induction through the conductive layer.

In some embodiments, the LED may comprise an array of LEDs disposed on a substrate, the glass panel is disposed on top of the array of LEDs, and the substrate is disposed on a stage that is configured to move in a plane perpendicular to an optical axis of the camera, and capturing the image using the camera based on the light emitted from the LED may comprise: capturing a first image of a first LED set of the array of LEDs within a field of view of the camera; moving the stage relative to the camera to place a second LED set of the array of the LEDs within the field of view of the camera, wherein the second LED set contains at least some LEDs not present in the first LED set; and capturing a second image of the second LED set.

In some embodiments, before applying the radio frequency signal to the glass panel, the method may further comprise dicing the substrate to electrically separate each LED of the array of LEDs.

In some embodiments, the method may further comprise: singulating the substrate to physically separate each LED of the array of LEDs; and transferring each functioning LED of the array of LEDs to a display assembly.

In some embodiments, determining, using the processor, whether the LED is a defective LED or a functioning LED may comprise: determining an illumination intensity of the LED based on the image; and comparing the illumination intensity of the LED to a preset threshold. The LED may be a defective LED if the illumination intensity is less than the preset threshold, and the LED may be a functioning LED if the illumination intensity is greater than or equal to the preset threshold.

### DESCRIPTION OF THE DRAWINGS

For a fuller understanding of the nature and objects of the disclosure, reference should be made to the following detailed description taken in conjunction with the accompanying drawings, in which:

FIG. 1 is a cross-sectional side view of a system according to an embodiment of the present disclosure;

FIG. 2A is a schematic diagram of a lateral chip LED according to an embodiment of the present disclosure;

FIG. 2B is a schematic diagram of a flip-chip LED according to an embodiment of the present disclosure;

FIG. 2C is a schematic diagram of a vertical chip LED according to an embodiment of the present disclosure;

FIG. 3 is a schematic diagram of a processor according to an embodiment of the present disclosure;

FIG. 4A is a top view of a substrate according to an embodiment of the present disclosure, where all LEDs on the substrate are captured within the field of view of the camera;

FIG. 4B is a top view of a substrate according to an embodiment of the present disclosure, where a first set of LEDs are captured within the field of view of the camera;

FIG. 4C is a top view of a substrate according to an embodiment of the present disclosure, where a second set of LEDs are captured within the field of view of the camera, after the stage is moved from the position shown in FIG. 4B;

FIG. 5 is a flowchart of a method according to an embodiment of the present disclosure; and

FIG. 6 is a flow chart of the steps of capturing an image of the LED according to an embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process, step, and electronic changes may be made without departing from the scope of the disclosure. Accordingly, the scope of the disclosure is defined only by reference to the appended claims.

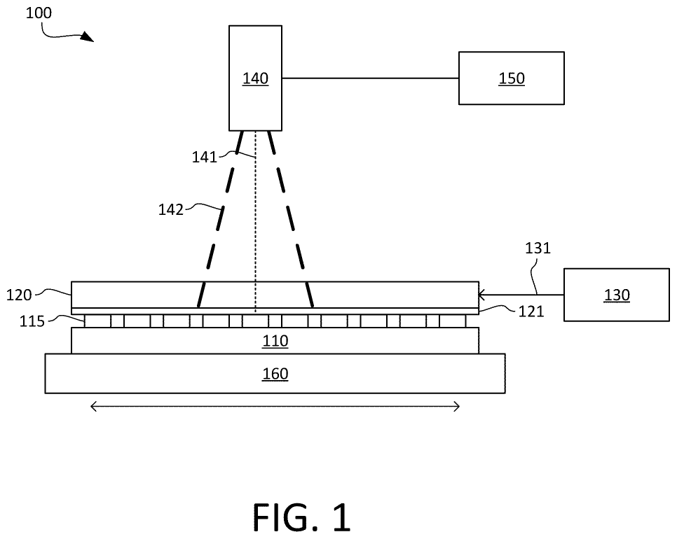

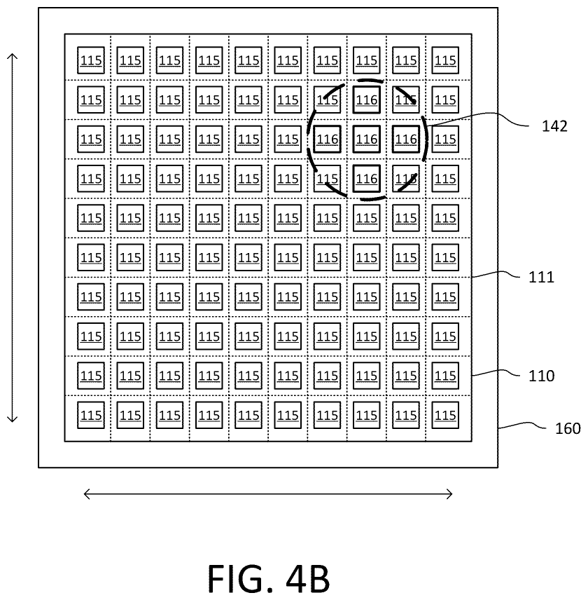

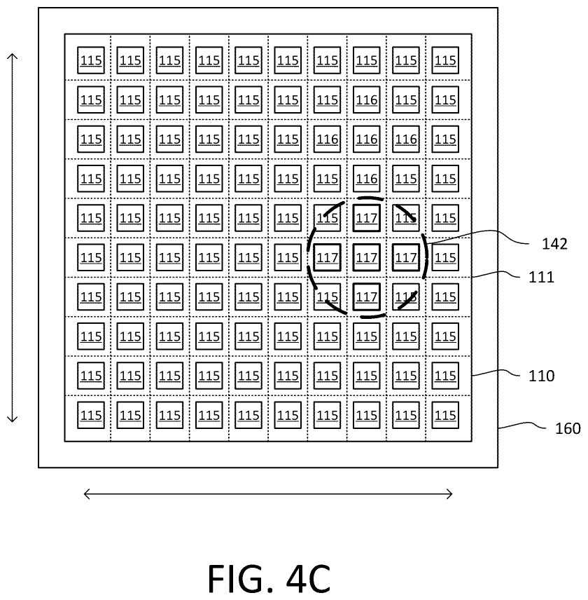

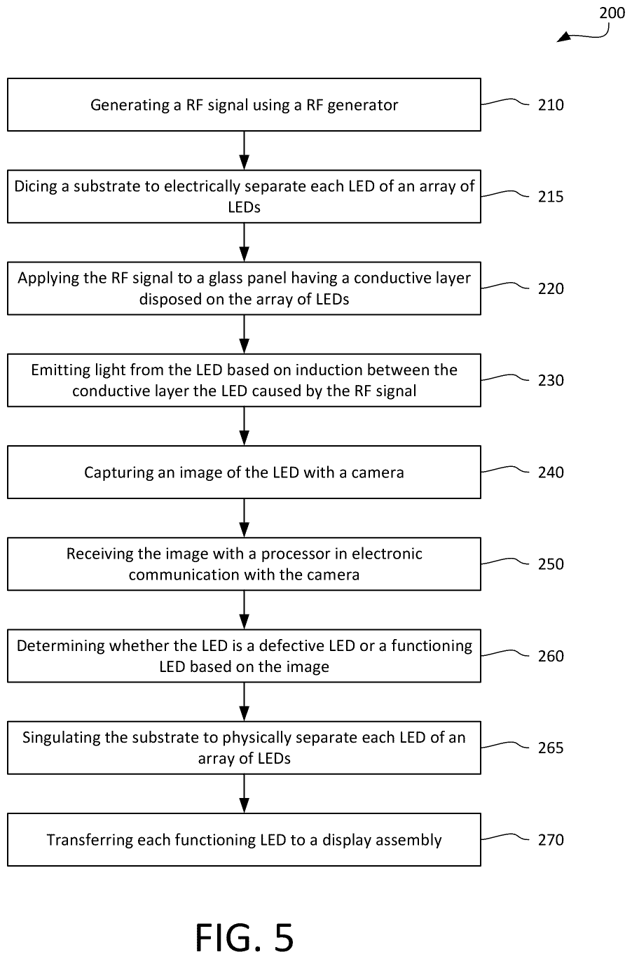

An embodiment of the present disclosure provides a system 100. The system 100 may be part of a semiconductor manufacturing system, for example, in the fabrication of micro LEDs for micro LED display panels. As shown in FIG. 1, the system 100 may comprise a substrate 110 (e.g., a semiconductor substrate) having at least one LED 115 disposed thereon. In some embodiments, there may be an array of LEDs 115 disposed on the substrate 110. The substrate 110 may be comprised of GaAs, GaN, or other semiconductor wafer materials. The substrate 110 may be rectangular, square, circular, or other shapes. In some instances, the substrate 110 may have a width/diameter of 2-8 inches (e.g., 2, 3, 4, 6, or 8 inches, and any size therebetween). During the fabrication process of the LEDs 115, each LED may be electrically connected together. A dicing process may be used to electrically separate (i.e., sever the electrical connections) the LEDs 115, and then a singulation process may be used to physically separate each LED 115 from each other and from the substrate 110 for placement in a display panel assembly. The singulation process may comprise elastomer stamping, electrostatic transfer, electromagnetic transfer, laser-assisted, transfer, fluid self-assembly, or any other mass transfer process used to transfer each LED 115 from the substrate 110 to a target substrate. Perforations 111 (shown in FIGS. 4A-4C) may represent the lines on which the dicing and singulation processes may be performed on the substrate 110. Additional perforations may be present to undercut portions of the LED 115 connected to the substrate 110, according to the structure of the LEDs 115 and the singulation process. The LEDs 115 may be micro LEDs (e.g., less than 100 μm in length and width and less than 8 μm in height) or other sizes. For example, each LED 115 may be 10 μm by 10 μm. Based on the size of the substrate 110 and the size of each LED 115, there may be over 1,000,000 LEDs 115 disposed on the substrate 110. Each LED 115 shown in FIG. 1 and FIGS. 5A-5C may represent a single LED or an array of LEDs. Accordingly, additional perforations 111 may be present to separate each LED of the array of LEDs within each illustrated LED 115.

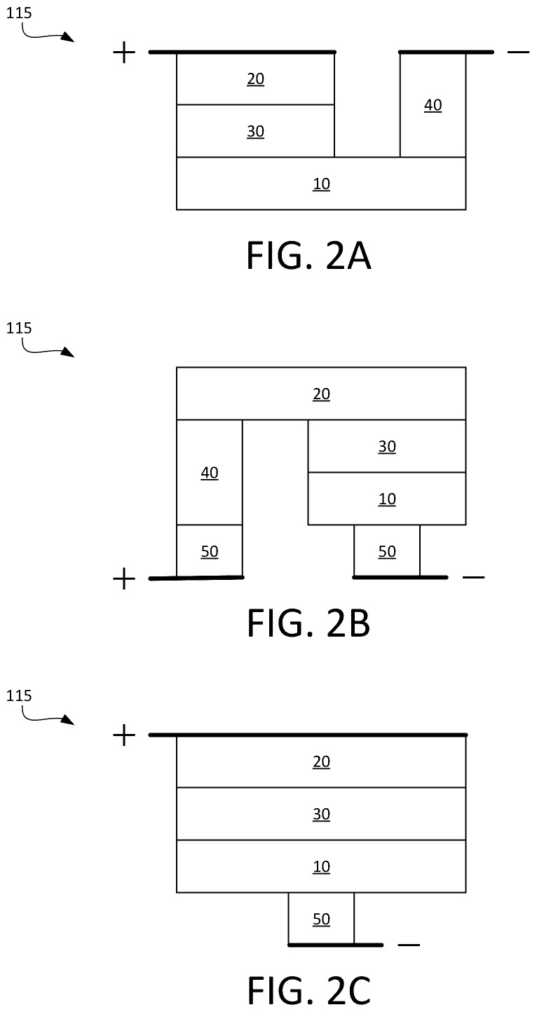

The LEDs 115 may have various structure, such as lateral chip (shown in FIG. 2A), flip-chip (shown in FIG. 2B), vertical chip (shown in FIG. 2C), or other structures. In general, each LED 115 may comprise an N-doped layer 10, a P-doped layer 20, and a multiple quantum well layer 30 disposed between N-doped layer 10 and the P-doped layer 20. Connecting a negative electrode to the N-doped layer 10 and connecting a positive electrode to the P-doped layer 20 causes a forward bias between the N-doped layer 10 and the P-doped layer 20, via the multiple quantum well layer 30, which generates photons to emit light. In the lateral chip structure shown in FIG. 2A, a metal post 40 is disposed on the N-doped layer 10. The negative electrode is connected to the metal post 40, and the positive electrode is connected to the P-doped layer 20. In the flip-chip structure shown in FIG. 2B, a metal post 40 is disposed on the P-doped layer 20, and a bonding layer 50 is disposed on the N-doped layer 10 and the metal post 40. The negative electrode is connected to the bonding layer 50 on the N-doped layer 10, and the positive electrode is connected to the bonding layer 50 on the metal post 40. In the vertical chip structure shown in FIG. 2C, a bonding layer 50 is disposed on the N-doped layer 10. The negative electrode is connected to the bonding layer 50, and the positive electrode is connected to the P-doped layer 20.

The system 100 may further comprise a glass panel 120. The glass panel 120 may have a thickness of 0.7 mm to 5 mm. The glass panel 120 may be disposed on the substrate 110, on top of the LED 115. For example, the glass panel 120 may be disposed on top of each LED 115 of the array of LEDs. The glass panel 120 may be transparent, so that the LED 115 is visible through the glass panel 120. The glass panel 120 may also protect the LED 115 during testing. The glass panel 120 may comprise a conductive layer 121. The conductive layer 121 may have a thickness of 150 nm to 200 nm. The conductive layer 121 may comprise indium tin oxide (ITO), zinc oxide (ZnO), or organic transparent and conductive films comprised of other conductive materials. The thickness of the conductive layer 121 may be selected to maintain visibility through the glass panel 120. In other words, the conductive layer 121 may have a thickness that maintains its transparency for visibility through the glass panel 120. The conductive layer 121 may cover the bottom surface of the glass panel 120 that is in contact with the LED 115 or array of LEDs.

The system 100 may further comprise a radio frequency (RF) generator 130. The RF generator 130 may be configured to apply a radio frequency signal 131 to the glass panel 120. The RF signal 131 may have a frequency of 5 to 10 MHz. The RF signal 131 may have a voltage amplitude of 10 V to 50 V. The RF signal 131 may be a sine wave or a square wave. When the RF signal 131 is applied to the glass panel 120, the LED 115 may be illuminated by induction through the conductive layer 121. For example, the RF signal 131 may cause a forward bias between the N-doped layer 10 and the P-doped layer 20 of the LED 115, which may generate photons, thereby illuminating the LED 115. The RF signal 131 may simultaneously illuminate each LED 115 of the array of LEDs. The illumination intensity of the LED 115 may indicate whether the LED 115 is a defective LED or a functioning LED. For example, an LED 115 that fails to illuminate (i.e., 0 illumination intensity) may indicate a defective LED and an LED that produces some illumination (i.e., non-zero illumination intensity) may indicate a functioning LED. Alternatively, the illumination intensity may be based on a non-zero threshold to indicate whether the LED 115 is a defective LED or a functioning LED. The LED 115 may emit light through the glass panel 120, so as to be visible from the other side.

The system 100 may further comprise a camera 140. The camera 140 may be a CMOS camera or other camera sensor configured to detect light within a wavelength range emitted by the LED 115. The camera 140 may be disposed above the glass panel 120. The camera 140 may have an optical axis 141 that is perpendicular to the glass panel 120, and may have a field of view 142. The camera 140 may be configured to capture an image of the LED 115 illuminated by the RF signal 131 within the field of view 142. The field of view 142 may encompass the entire substrate 110 to capture an image of all of the LEDs 115 on the substrate (as shown in FIG. 4A), or a portion of the substrate 110 to capture an image of some of the LEDs 115 on the substrate (as shown in FIG. 4B and FIG. 4C). The field of view 142 may depend on the position of the camera 140 relative to the substrate 110 and the resolution of the camera 140. For example, a camera 140 positioned farther away from the substrate 110 may have a field of view 142 that encompasses more of the substrate 110 compared to a camera 140 positioned closer to the substrate 110, but may require a higher resolution to accurately identify each LED 115. Accordingly, the field of view 142 may be adjusted according to system requirements.

The system 100 may further comprise a processor 150. The processor 150 may include a microprocessor, a microcontroller, or other devices.

The processor 150 may be coupled to the components of the system 100 in any suitable manner (e.g., via one or more transmission media, which may include wired and/or wireless transmission media) such that the processor 150 can receive output. The processor 150 may be configured to perform a number of functions using the output. A wafer inspection tool can receive instructions or other information from the processor 150. The processor 150 optionally may be in electronic communication with another wafer inspection tool, a wafer metrology tool, or a wafer review tool (not illustrated) to receive additional information or send instructions.

The processor 150 may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor 150 may be disposed in or otherwise part of the system 100 or another device. In an example, the processor 150 and may be part of a standalone control unit or in a centralized quality control unit. Multiple processors 150 may be used, defining multiple subsystems of the system 100.

The processor 150 may be implemented in practice by any combination of hardware, software, and firmware. Also, its functions as described herein may be performed by one unit, or divided up among different components, each of which may be implemented in turn by any combination of hardware, software and firmware. Program code or instructions for the processor 150 to implement various methods and functions may be stored in readable storage media, such as a memory.

If the system 100 includes more than one subsystem, then the different processors 150 may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 150 may be configured to perform a number of functions using the output of the system 100 or other output. For instance, the processor 150 may be configured to send the output to an electronic data storage unit or another storage medium. The processor 150 may be further configured as described herein.

The processor 150 may be configured according to any of the embodiments described herein. The processor 150 also may be configured to perform other functions or additional steps using the output of the system 100 or using images or data from other sources.

The processor 150 may be communicatively coupled to any of the various components or sub-systems of system 100 in any manner known in the art. Moreover, the processor 150 may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the processor 150 and other subsystems of the system 100 or systems external to system 100. Various steps, functions, and/or operations of system 100 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random access memory, a magnetic or optical disk, a non-volatile memory, a solid state memory, a magnetic tape, and the like. A carrier medium may include a transmission medium such as a wire, cable, or wireless transmission link. For instance, the various steps described throughout the present disclosure may be carried out by a single processor 150 (or computer subsystem) or, alternatively, multiple processors 150 (or multiple computer subsystems). Moreover, different sub-systems of the system 100 may include one or more computing or logic systems. Therefore, the above description should not be interpreted as a limitation on the present disclosure but merely an illustration.

The processor 150 may be in electronic communication with the camera 140. The processor 150 may be configured to receive the image from the camera 140, and determine whether the LED 115 is a defective LED or a functioning LED based on the image of the LED 115.

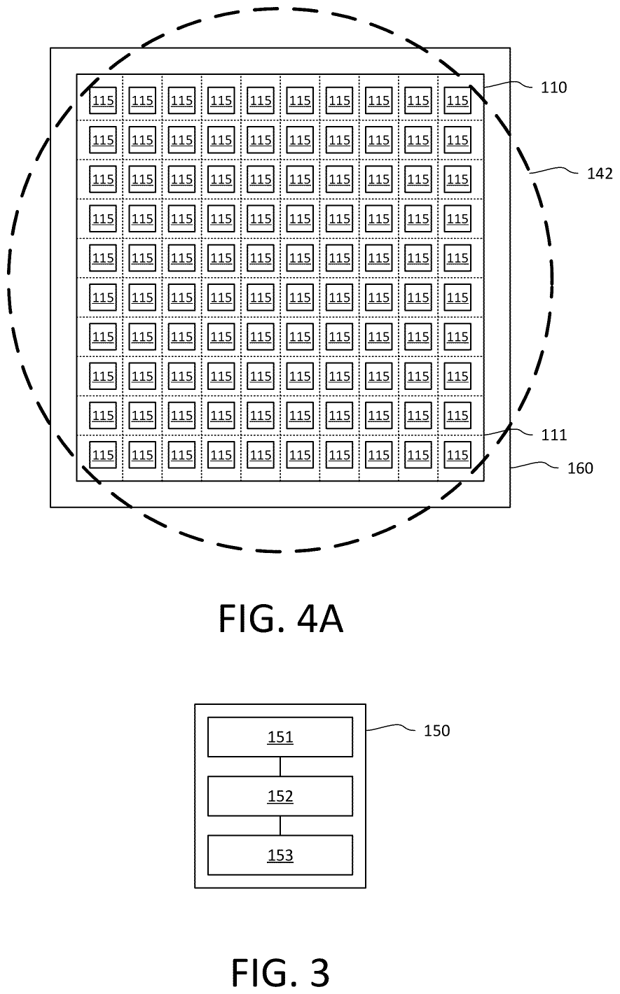

In some embodiments, the processor 150 may comprise a receiving circuit 151, an extracting circuit 152, and a determining circuit 153, as shown in FIG. 3. The receiving circuit 151 may be configured to receive the image from the camera 140. The extracting circuit 152 may be configured to extract an illumination intensity of the LED 115 based on the image received by the receiving circuit 151. For example, for each LED 115 shown in the image, the extracting circuit 152 may identify an illumination intensity of the LED 115 from the image. The determining circuit 153 may be configured to determine whether the LED 115 is a defective LED or a functioning LED based on the illumination intensity of the LED 115 extracted by the extracting circuit 152. The determining circuit 153 may be further configured to compare the illumination intensity of the LED 115 to a preset threshold. The LED 115 may be determined to be a defective LED if the illumination intensity is less than the preset threshold, and the LED 115 may be determined to be a functioning LED if the illumination intensity is greater than or equal to the preset threshold. In some embodiments, the preset threshold may be 0. In other words, a defective LED may emit no light (i.e., appear black) in the image. In other embodiments, the preset threshold may be non-zero. In other words, a defective LED may emit some light, but less than an amount considered to be a functioning LED. The preset threshold may be defined within the mid-dynamic range of the camera 140. Accordingly, the camera 140 may be selected based on its sensitivity to distinguish between defective LEDs and functioning LEDs within a normal operating range. The preset threshold may be defined based on test data, e.g., by setting a threshold value based on average results of defective LEDs and functioning LEDs. In some embodiments, the preset threshold may be defined such that the average separation of defective LEDs and functioning LEDs is 5 standard deviations apart. Other methods of analyzing the image of the LED 115 to determine whether the LED 115 is a defective LED or a functioning LED are possible (e.g., based on grayscale values), and is not limited herein.

The system 100 may further comprise a stage 160. The substrate 110 may be disposed on the stage 160. The stage 160 may be configured to move relative to the camera 140. For example, the stage 160 may be configured to move in a plane perpendicular to the camera 140, as shown in FIG. 4A. The stage 160 may be movable by one or more actuators or other means and is not limited herein. Alternatively, the camera 140 may be configured to move relative to the stage 160. When the stage 160 moves relative to the camera 140, LEDs 115 may be moved in or out of the field of view 142. For example, the camera 140 may capture an image of a first set of LEDs 116 within the field of view 142 (as shown in FIG. 4B), based on the size of the field of view 142, and by moving the stage 160, the camera may capture an image of a second set of LEDs 117 within the field of view 142 (as shown in FIG. 4C). The LEDs 115 within the first set of LEDs 116 and the second set of LEDs 117 may be mutually exclusive or may overlap. By capturing images of the first set of LEDs 116, the second set of LEDs 117, and any number of additional sets of LEDs, images of each LED 115 of the array of LEDs may be captured by the camera 140.

In some embodiments, the field of view 142 may encompass the entire substrate 110 (as shown in FIG. 4A), and the camera 140 may capture a first image of each of the LEDs 115 on the substrate 110. Then, the field of view 142 may be focused onto the first set of LEDs 116 (as shown in FIG. 4B) or the second set of LEDs 117 (as shown in FIG. 4C) to capture a second image of particular LEDs. The field of view 142 may be focused by moving the stage 160 or the camera 140 or by one or more optical elements. Accordingly, the first image may be used to cover the whole substrate 110, and the second image may be used to cover a particular area of interest on the substrate 110. For example, if the processor 150 fails to determine whether an LED 115 is a defective LED or a functioning LED in the first image (e.g., based on poor image resolution or inconclusive illumination intensity), the second image may be captured to determine whether the LED 115 is a defective LED or a functioning LED with a focused, higher resolution image.

The processor 150 may be in electronic communication with the actuators or other means configured to move the stage 160. In particular, the processor 150 may control the one or more actuators to move the stage 160 in a particular sequence in order to capture images of each LED 115 on the substrate 110. The processor 150 may also track the position of the stage 160 and the position of each LED 115 under test. Accordingly, the processor 150 may map the position of each LED 115 to the decision whether the LED 115 is a defective LED or a functioning LED. This mapping may be used to identify the functioning LEDs that can be used, and the defective LEDs that can be discarded.

With the system 100, the RF generator 130 may apply the RF signal 131 to the glass panel 120 to illuminate the LEDs 115 by induction, and the camera 140 can capture an image of the LEDs 115 to determine whether each LED 115 is a defective LED or a functioning LED. The system may therefore allow efficient testing of large amounts of micro LEDs manufactured on a substrate 110, so that defective LEDs are identified and not transferred to a display assembly.

Another embodiment of the present disclosure provides a method 200. With reference to FIG. 5, the method 200 may comprise the following steps.

At step 210, a radio frequency signal is generated using a radio frequency generator. The RF signal may have a frequency of 5 to 10 MHz. The RF signal may have a voltage amplitude of 10 V to 50 V. The RF signal may be a sine wave or a square wave.

At step 220, the RF signal is applied to a glass panel disposed on top of an LED. The LED may be disposed on a substrate comprising an array of LEDs. The LEDs may be planar (i.e., surface mounted) or vertical (i.e., through-hole mounted) LEDs. The LEDs may be micro LEDs (e.g., less than 100 μm in size) or other sizes. The glass panel may be disposed on each LED of the array of LEDs. The glass panel may have a thickness of 0.7 mm to 5 mm. The glass panel may be transparent, so that each LED is visible through the glass panel. The glass panel may comprise a conductive layer. The conductive layer may have a thickness of 150 nm to 200 nm. The conductive layer may comprise indium tin oxide (ITO), zinc oxide (ZnO), or organic transparent and conductive films comprised of other conductive materials. The thickness of the conductive layer may be selected to maintain visibility through the glass panel. In other words, the conductive layer may have a thickness that maintains its transparency for visibility through the glass panel. The conductive layer may cover the bottom surface of the glass panel that is in contact with the LED.

At step 230, light is emitted from the LED based on induction between the conductive layer and the LED caused by the RF signal. For example, the RF signal may cause a forward bias between the N-doped layer and the P-doped layer of the LED 115, which may generate photons, thereby illuminating the LED. The RF signal may simultaneously illuminate each LED of the array of LEDs. The illumination intensity of each LED may indicate whether the LED is a defective LED or a functioning LED. For example, an LED that fails to illuminate (i.e., 0 illumination intensity) may indicate a defective LED and an LED that produces some illumination (i.e., non-zero illumination intensity) may indicate a functioning LED. Alternatively, the illumination intensity may be based on a non-zero threshold to indicate whether the LED is a defective LED or a functioning LED. The LED may emit light through the glass panel, so as to be visible from the other side.

At step 240, an image is captured with a camera based on the light emitted from the LED. The camera may be a CMOS camera or other camera sensor configured to detect light within a wavelength range emitted by the LED. The camera may be disposed above the glass panel. The camera may have an optical axis that is perpendicular to the glass panel, and a field of view. The camera may capture an image of the LED illuminated by the RF signal within the field of view. The field of view may encompass the entire substrate to capture an image of all of the LEDs on the substrate, or a portion of the substrate to capture an image of some of the LEDs on the substrate. The field of view may depend on the position of the camera relative to the substrate and the resolution of the camera. For example, a camera positioned farther away from the substrate may have a field of view that encompasses more of the substrate compared to a camera positioned closer to the substrate, but may require a higher resolution to accurately identify each LED. Accordingly, the field of view may be adjusted according to system requirements.

At step 250, the image is received by a processor in electronic communication with the camera. For example, the camera may be connected to the processor to send the image by wired and/or wireless transmission.

At step 260, the processor determines whether the LED is a defective LED or a functioning LED based on the image of the LED. For example, the processor may extract an illumination intensity of the LED from the image, and may compare the illumination intensity of the LED to a preset threshold to determine whether the LED is a defective LED or a functioning LED. The LED may be determined to be a defective LED if the illumination intensity is less than the preset threshold, and the LED may be determined to be a functioning LED if the illumination intensity is greater than or equal to the preset threshold. In some embodiments, the preset threshold may be 0. In other words, a defective LED may emit no light (i.e., appear black) in the image. In other embodiments, the preset threshold may be non-zero. In other words, a defective LED may emit some light, but less than an amount considered to be a functioning LED. The preset threshold may be defined within the mid-dynamic range of the camera. Accordingly, the camera may be selected based on its sensitivity to distinguish between defective LEDs and functioning LEDs within a normal operating range. The preset threshold may be defined based on test data, e.g., by setting a threshold value based on average results of defective LEDs and functioning LEDs. In some embodiments, the preset threshold may be defined such that the average separation of defective LEDs and functioning LEDs is 5 standard deviations apart. Other methods of analyzing the image to determine whether the LED is a defective LED or a functioning LED are possible (e.g., based on grayscale values), and is not limited herein.

In some embodiments, before applying the RF signal to the glass panel at step 220, the method 200 may further comprise step 215. At step 215, the substrate is diced to electrically separate each LED of the array of LEDs. During the fabrication process of the LEDs, each LED may be electrically connected together. By dicing the substrate, the electrical connections between each LED may be severed, in order to separately induce illumination of each LED.

In some embodiments, the method 200 may further comprise the following steps.

At step 265, the substrate is singulated to physically separate each LED of the array of LEDs. By singulating the substrate, each LED can be physically separated from each other. For example, the functioning LEDs can be separated from the defective LEDs, as determined by the processor. The singulation process may comprise elastomer stamping, electrostatic transfer, electromagnetic transfer, laser-assisted, transfer, fluid self-assembly, or any other mass transfer process used to transfer each LED from the substrate to a target substrate.

At step 270, each functioning LED of the array of LEDs may be transferred to a display assembly. The functioning LEDs may be transferred manually or by a pick and place robot. The method of transfer may depend on the type of singulation process used, and is not limited herein. When there are a group of functioning LEDs in proximity to each other, the group of functioning LEDs may be transferred to the display assembly together. Each defective LED may not be transferred to the display assembly. For example, each defective LED may remain on the substrate or may be discarded.

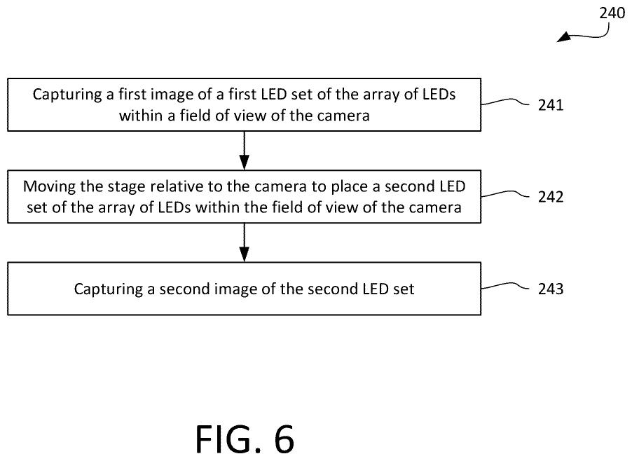

In some embodiments, the substrate may be disposed on a stage that is configured to move in a plane perpendicular to an optical axis of the camera. Accordingly, capturing the image using the camera based on the light emitted from the LED at step 240 may comprise the following steps shown in FIG. 6.

At step 241, a first image is captured of a first LED set of the array of LEDs within field of view of the camera. The first LED set may comprise all of the LEDs of the array of LEDs or some of the LEDs of the array of LEDs.

At step 242, the stage is moved relative to the camera to place a second LED set of the array of the LEDs within the field of view of the camera. The second LED set may contain at least some LEDs not present in the first LED set or may be a subset of the first LED set.

At step 243, a second image of the second LED set is captured with the camera.

Step 242 and step 243 may be repeated any number of times to place further sets of LEDs within the field of view of the camera and capture images of each LED disposed on the substrate. Each image may be received by the processor, which can determine whether each LED in the respective image is a defective LED or a functioning LED in step 250 and step 260 described above.

With the method 200, the RF signal applied to the glass panel may be used to induce illumination of the LEDs, and the light emitted by the LEDs may be captured by the camera to determine whether each LED is a defective LED or a functioning LED. The method 200 may therefore allow efficient testing of large amounts of micro LEDs manufactured on a substrate, so that defective LEDs are identified and not transferred to a display assembly.

Although the present disclosure has been described with respect to one or more particular embodiments, it will be understood that other embodiments of the present disclosure May be made without departing from the scope of the present disclosure. Hence, the present disclosure is deemed limited only by the appended claims and the reasonable interpretation thereof.

What is claimed is:

1. A system comprising:
a glass panel comprising a conductive layer, wherein the conductive layer is disposed on top of an LED;
a radio frequency generator configured to apply a radio frequency signal to the glass panel, wherein the radio frequency signal illuminates the LED by induction through the conductive layer;
a camera configured to capture an image of the LED illuminated by the radio frequency signal; and
a processor in electronic communication with the camera that is configured to:
receive the image from the camera; and
determine whether the LED is a defective LED or a functioning LED based on the image of the LED.

2. The system of claim 1, wherein the radio frequency signal has a frequency of 5 to 10 MHz.

3. The system of claim 1, wherein the LED comprises an array of LEDs disposed on a substrate, and the glass panel is disposed on top of the array of LEDs.

4. The system of claim 3, wherein the radio frequency signal applied to the glass panel simultaneously illuminates each LED of the array of LEDs by induction through the conductive layer.

5. The system of claim 3, further comprising:
a stage configured to move in a plane perpendicular to an optical axis of the camera, wherein the substrate is disposed on the stage;
wherein the camera is configured to capture an image of at first LED set of the array of LEDs within a field of view of the camera, and by moving the stage relative to the camera, the camera is further configured to capture an image of a second LED set of the array of LEDs within the field of view of the camera, the second LED set containing at least some LEDs not present in the first LED set or a subset of the first LED set.

6. The system of claim 1, wherein the LED has a lateral chip structure.

7. The system of claim 1, wherein the conductive layer is disposed on a bottom surface of the glass panel, and the LED contacts the conductive layer.

8. The system of claim 1, wherein the conductive layer comprises indium tin oxide (ITO).

9. The system of claim 1, wherein the processor is configured to determine whether the LED is a defective LED or a functioning LED by:
determining an illumination intensity of the LED based on the image; and
comparing the illumination intensity of the LED to a preset threshold;
wherein the LED is a defective LED if the illumination intensity is less than the preset threshold, and the LED is a functioning LED if the illumination intensity is greater than or equal to the preset threshold.

10. A method comprising:
generating a radio frequency signal using a radio frequency generator;
applying the radio frequency signal to a glass panel, wherein the glass panel comprises a conductive layer, and the conductive layer is disposed on top of an LED;
emitting light from the LED based on induction between the conductive layer and the LED caused by the radio frequency signal;
capturing an image using a camera based on the light emitted from the LED; and
determining, using a processor, whether the LED is a defective LED or a functioning LED based on the image of the LED.

11. The method of claim 10, wherein the radio frequency signal has a frequency of 5 to 10 MHz.

12. The method of claim 10, wherein the LED comprises an array of LEDs disposed on a substrate, and the glass panel is disposed on top of the array of LEDs.

13. The method of claim 12, wherein applying the radio frequency signal to the glass panel simultaneously illuminates the array of LEDs by induction through the conductive layer.

14. The method of claim 12, wherein the substrate is disposed on a stage that is configured to move in a plane perpendicular to an optical axis of the camera, and capturing the image using the camera based on the light emitted from the LED comprises:
capturing a first image of a first LED set of the array of LEDs within a field of view of the camera;
moving the stage relative to the camera to place a second LED set of the array of the LEDs within the field of view of the camera, wherein the second LED set contains at least some LEDs not present in the first LED set or a subset of the first LED set; and
capturing a second image of the second LED set.

15. The method of claim 12, wherein, before applying the radio frequency signal to the glass panel, the method further comprises:
dicing the substrate to electrically separate each LED of the array of LEDs.

16. The method of claim 12, further comprising:
singulating the substrate to physically separate each LED of the array of LEDs; and
transferring each functioning LED of the array of LEDs to a display assembly.

17. The method of claim 10, wherein the LED has a lateral chip structure.

18. The method of claim 10, wherein the conductive layer is disposed on a bottom surface of the glass panel, and the LED contacts the conductive layer.

19. The method of claim 10, wherein the conductive layer comprises indium tin oxide (ITO).

20. The method of claim 10, wherein determining, using the processor, whether the LED is a defective LED or a functioning LED comprises:
determining an illumination intensity of the LED based on the image; and
comparing the illumination intensity of the LED to a preset threshold;
wherein the LED is a defective LED if the illumination intensity is less than the preset threshold, and the LED is a functioning LED if the illumination intensity is greater than or equal to the preset threshold.
